(19) United States
(12) Patent Application Publication
(10) Pub. No.: US 2010/0068453 A1
(43) Pub. Date: Mar. 18, 2010

(54) METHOD FOR PRODUCING PROCESSED GLASS SUBSTRATE

(76) Inventors: Hirofumi IMAI, Kawasaki-shi (JP); Koichi Misumi, Kawasaki-shi (JP); Takahiro Asai, Kawasaki-shi (JP)

Correspondence Address: WENDEROTH, LIND & PONACK, L.L.P., 1030 15th Street, N.W.,, Suite 400 East, Washington, DC, 20005-1503, US

(21) Appl. No.: 12/558,850

(22) Filed: Sep. 14, 2009

(30) Foreign Application Priority Data
Sep. 18, 2008 (JP) 2008-239294
Sep. 18, 2008 (JP) 2008-239301

(51) Int. Cl. B32B 3/24; C03C 19/00; C03C 15/00; G03F 7/20

(52) U.S. Cl. 428/131; 65/23; 65/30.1; 430/322; 430/325

(57) ABSTRACT

A processed substrate of the present invention includes a translucent substrate having a plurality of through-holes, in each of which there is a gap from 0 to 5 μm between (a) a straight line which passes through a central point of an opening plane of the each of the plurality of through-holes and which is perpendicular to the opening plane and (b) a straight line which passes through a central point of the other opening plane of the each of the plurality of through-holes and which is perpendicular to the other opening plane, thereby making it possible to provide (i) a processed substrate having through-holes in each of which central axes are aligned, which can be easily produced with high productivity, and (ii) a production method thereof. Further, a production method of the present invention of a processed glass substrate includes: (a) forming photosensitive resin layers on surfaces of a glass substrate; (b) forming a through-hole in the glass substrate; and (c) immersing the glass substrate in acid, with the photosensitive resin layers remaining on the both surfaces. Accordingly, it is unnecessary to perform smoothing the surfaces of the glass substrate after the step (c), thereby successfully producing a processed glass substrate having a through-hole with high productivity.

This Nonprovisional application claims priority under 35 U.S.C. §119(a) on Patent Application No. 2008-239294 and Patent Application No. 2008-239301 each filed in Japan on Sep. 18, 2008, the entire contents of which are hereby incorporated by reference.

### TECHNICAL FIELD

The present invention relates to a processed substrate used as, for example, a support plate, a method for producing the processed substrate, and a method for producing a processed glass substrate.

### BACKGROUND ART

In recent years, it has been desired that a semiconductor chip be microfabricated, with a view to multiple functioning of a system, an improvement in operating frequency, and higher integration.

The microfabrication of the semiconductor chip can be attained, for example, by forming a wafer, which is to be a substrate, so as to be reduced in thickness. However, the wafer thus reduced in thickness extremely decreases in strength, thereby causing, for example, a defect such as a breakage or a crack due to slight contact or thermal stress during handling. In order to supplement the strength of the wafer in processing, a processed substrate made of glass or the like is used as a support plate for supporting the wafer, in some cases.

As a technique related to such a processed substrate, Patent Literature 1 [Japanese Patent Application Publication, Tokukai, No. 2001-185519 A, (Publication Date: Jul. 6, 2001)] discloses the following processed substrate. A support substrate (processed substrate) employed in Patent Literature 1 has a two-layer structure in which a support substrate having through-holes is bonded to a support substrate having no through-hole. This structure allows a wafer to be easily removed from the support substrate after the wafer is processed.

In a case where a processed substrate is used to support the wafer, since the processed substrate is once bonded to the wafer by an adhesive or the like, a process of stripping off the processed substrate from the wafer by use of a removing solution or the like is required. For this reason, a through-hole is provided in the processed substrate so that, when the removing solution is poured from one opening of the through-hole with the other opening contacting with the wafer, the removing solution easily comes into contact with the adhesive applied between the wafer and the processed substrate.

Such a processed substrate having a through-hole may be produced in the following method, for example. Photosensitive resin layers are formed on both surfaces of a substrate as a base material. One (first surface) of the both surfaces of the substrate is exposed to an irradiation pattern and then developed so as to form a pattern. The first surface is then etched along the pattern and is holed until the hole reaches in the vicinity of a center of the substrate. After that, the other one (second surface) of the surfaces is patterned and etched. At this time, in order that respective holes formed on the first surface and the second surface become a through-hole in which central axes of the respective holes are aligned, the second surface is patterned so that a pattern to be formed thereon is positioned right at a position of the hole formed in the first surface. As such, the through-hole is formed in the processed substrate. However, at this time, there may be caused a rough spot called “burr” in an inner wall of the through-hole when the first and second surfaces are holed. The burr may cause cracks or the like in the substrate and cause a decrease in strength of glass itself. For this reason, it is preferable that the burr is removed. In order to remove that burr formed in the through-hole, which may cause cracks, the photosensitive resin layers remaining on the substrate are stripped from the substrate and the substrate is immersed in acid. Since the immersion causes the surfaces of the substrate to be rough due to erosion by the acid, the surfaces are polished to be smoothed. In this way, the processed substrate is produced. However, the above method may cause the following problems.

That is, in the above method, after the first surface is patterned and holed, the second surface is patterned. At this time, it is necessary that a pattern to be formed on the second surface be positioned right at the position of the hole formed in the first surface. However, since the processed substrate is to be used by being attached to a microfabricated wafer, the processed substrate, as well as the wafer, is also microfabricated and a through-hole to be formed is therefore extremely minute. On this account, in a case where a hole is to be formed in the second surface, which is opposite to the first surface in which the hole has been formed, it is very difficult to form a pattern on the second surface right at the position of the hole formed in the first surface. This easily causes a gap between (a) a central axis of an opening plane of the hole formed in the first surface and (b) a central axis of an opening plane of the hole formed in the second surface. Especially in a case where a large substrate is to be holed, these problems are significant. Such a gap may cause cracks (breakage or defect), which results in a decrease in strength of the processed substrate itself.

Further, since the substrate in which the through-hole is formed is immersed in acid, surface portions of the substrate are also eroded in addition to the through-hole. At this time, in a case where there is no arrangement to protect the surface portions of the substrate, the surface portions become rough due to erosion by the acid. Therefore, it is necessary to carry out smoothing of the surfaces of the substrate, after the immersing process. Patent Literature 1 does not disclose that method for forming a hole in a support substrate which resolves these problems or a method for removing a burr in a support substrate that has been holed, while erosion, due to acid, of a surface of the substrate is prevented.

### SUMMARY OF INVENTION

The present invention is accomplished in view of these problems. An object of the present invention is to provide a processed substrate which has a through-hole in which central axes of opening planes at both ends of the through-hole are aligned and which can be used as a support plate, and a method for easily producing the processed substrate with high productivity.

Further, another object of the present invention is to provide a method for producing a processed glass substrate having a through-hole, with high productivity, which method does not require smoothing of a surface of the processed glass substrate after an immersing process.

A processed substrate according to the present invention includes a translucent substrate having a plurality of through-holes, each of which plurality of through-holes being such that there is a gap in a range of 0 to 5 μm between (a) a straight line which passes through a central point of an opening plane of the each of the plurality of through-holes and which is perpendicular to the opening plane and (b) a straight line which passes through a central point of the other opening plane of the each of the plurality of through-holes and which is perpendicular to the other opening plane.

Further, a method according to the present invention for producing a processed substrate is a method for producing a processed substrate including a translucent substrate having a plurality of through-holes, and includes the steps of: (a) forming, by exposure, patterns of a plurality of through-holes on photosensitive resin layers provided on both surfaces of a translucent substrate; and (b) forming through-holes based on the patterns thus formed in the step (a), the step (a) irradiating one of the both surfaces of the translucent substrate with light so that the light passes through the translucent substrate toward the other surface, thereby exposing the photosensitive resin layers provided on the both surfaces of the translucent substrate.

In the processed substrate according to the present invention, each through-hole is such that there is a gap in a range of 0 to 5 μm between a straight line which passes through a central point of one opening plane of the each through-hole and which is perpendicular to the one opening plane and a straight line which passes through a central point of the other opening plane of the each through-hole and which is perpendicular to the other opening plane.

Further, in the method according to the present invention for producing a processed substrate, photosensitive resin layers provided on both surfaces of the substrate are exposed by irradiating a substrate with light from one surface of the substrate toward the other surface. As a result, it is possible to easily form a through-hole in which central axes of its opening planes are aligned, with high productivity.

A method, according to the present invention, for producing a processed glass substrate, includes the steps of: (a) forming photosensitive resin layers on both surfaces of a glass substrate; (b) after the step (a), forming at least one through-hole in the glass substrate; and (c) after the step (b), immersing the glass substrate in acid, with the photosensitive resin layers remaining on the both surfaces of the glass substrate.

The method, according to the present invention, for producing a processed glass substrate is a method for immersing in acid a glass substrate having a through-hole, with photosensitive resin layers remaining on the glass substrate, as such. Accordingly, surfaces of the glass substrate are protected by the photosensitive resin layers, thereby preventing erosion due to acid of the surfaces of the glass substrate during the immersing process (the step (c)). As a result, it is not necessary to carry out smoothing of the surfaces of the glass substrate after the immersing process, thereby successfully allowing producing a processed glass substrate having a through-hole with high productivity.

Additional objects, features, and strengths of the present invention will be made clear by the description below. Further, the advantages of the present invention will be evident from the following explanation in reference to the drawings.

### BRIEF DESCRIPTION OF THE DRAWINGS

FIG. 1

FIG. 1 illustrates one embodiment of how a processed substrate is produced, in accordance with the present invention.

FIG. 2

FIG. 2 illustrates one embodiment of how a processed glass substrate is produced, in accordance with the present invention.

FIG. 3

FIG. 3 is a cross-sectional view illustrating a plurality of through-holes in a processed substrate produced in Example 1.

FIG. 4

FIG. 4 is a cross-sectional view illustrating a through-hole in the processed substrate produced in Example 1.

FIG. 5

FIG. 5 is a cross-sectional view illustrating a plurality of through-holes in a processed substrate produced in Comparative Example 1.

FIG. 6

FIG. 6 is a cross-sectional view illustrating a through-hole in the processed substrate produced in Comparative Example 1.

FIG. 7

FIG. 7 illustrates a state of a hole portion in a processed substrate produced in Example 2.

FIG. 8

FIG. 8 illustrates a state of a hole portion in the processed substrate produced in Example 1.

FIG. 9

FIG. 9 illustrates a hole portion in a glass substrate that has not been subjected to an acid treatment, in Example 3.

FIG. 10

FIG. 10 illustrates a hole portion in a glass substrate that has been subjected to the acid treatment, in Example 3.

FIG. 11

FIG. 11 illustrates a hole portion, in a glass substrate, which has not been stress-relieved, in Example 4.

FIG. 12

FIG. 12 illustrates a hole portion, in a glass substrate, which has been stress-relieved, in Example 4.

### DESCRIPTION OF EMBODIMENTS

The following describes embodiments of the present invention with reference to drawings.

<1. Processed Substrate According to Present Invention>

A processed substrate according to the present invention includes a translucent substrate having a plurality of through-holes, each of the plurality of through-holes being such that there may be a gap in a range from 0 to 5 μm between (a) a straight line which passes through a central point of an opening plane of the each of the plurality of through-holes and which is perpendicular to the opening plane and (b) a straight line which passes through a central point of the other opening plane of the each of the plurality of through-holes and which is perpendicular to the other opening plane.

In the description, a processed substrate indicates a substrate that is processed so that through-holes are formed therein, and may be just referred to as “substrate”. A processed substrate according to the present invention can be used, for example, as a support substrate (support plate) that supports a wafer when the wafer is subjected to polishing or the like.

A material of the substrate is not especially limited, but may be a translucent material that has a property allowing light to pass therethrough, such as glass, quartz, sapphire, ceramics, or the like. In a case where such a translucent material is used and light is irradiated to a first surface of the translucent material, for example, the light passes through the translucent material to a second surface of the translucent material, thereby allowing exposing respective photosensitive resin layers provided on the first surface and the second surface, at the same time. A shape of the substrate is not limited in any particular manner, and may be, for example, a shape that allows the substrate to support a wafer in a case where the substrate is used as a support plate to support the wafer.

A through-hole is a hole formed to pass through a substrate. For example, the through-hole may be formed in such a manner that cone-shaped holes are formed in both surfaces of the substrate so that each cone-shaped hole formed in one of the both surfaces is communicated with a corresponding cone-shaped hole formed in the other surface, inside the substrate. Alternatively, the substrate may be holed from one surface thereof so as to form a through-hole. A shape of the hole is not limited to any particular shape, and may be, for example, an hourglass shape or a cylindrical shape. Further, a shape of an opening plane of the through-hole is not limited to any particular shape. In a case where the opening plane has, for example, a circular shape, its diameter may be in a range from 10 to 10,000 μm. Moreover, a depth of the through-hole is not limited in any particular manner, and may be 100 to 10,000 μm. The number of through-holes may be, for example, 1 to 1000 per square centimeter, but is not limited in any particular manner. The number of through-holes is preferably 10 to 600 per square centimeter, and more preferably 50 to 300 per square centimeter. In a case where a plurality of through-holes are provided, a distance between centers of through-holes provided closest to each other among them is preferably not less than 10 μm but not more than 10,000 μm, for example, but is not limited to this.

Further, in the processed substrate of the present invention, a through-hole is such that there may be a gap in a range from 0 to 5 μm, preferably no gap, between (a) a straight line (a central axis) which passes through a central point of an opening plane of the through-hole and which is perpendicular to the opening plane and (b) a straight line (a central axis) which passes through a central point of the other opening plane of the through-hole and which is perpendicular to the other opening plane. For example, in a case where the gap is not less than 6 μm, a cutting volume becomes large when a through-hole is formed, thereby causing a decrease in strength of the substrate, in some cases. In contrast, if the gap is in a range from 0 to 5 μm, then it is possible to form a through-hole with a less gap between the central axes of the opening planes, thereby making it possible to increase the strength. Moreover, in a case where the gap is in the range from 0 to 5 μm and the substrate is used as a support for wafer handling, it is possible to prevent adverse effects on a stripping process, i.e., impregnating the substrate with a removing solution in.

<2. Production Method According to Present Invention of Processed Substrate>

The following describes one embodiment of a production method, according to the present invention, of a processed substrate. However, the present invention is not limited to the following embodiment.

A production method, according to the present invention, for producing a processed substrate is a method for producing a processed substrate including a translucent substrate having a plurality of through-holes, and the production method includes the steps of: (a) forming, by exposure, patterns of a plurality of through-holes on photosensitive resin layers provided on both surfaces of a translucent substrate (a patterning process); and (b) forming through-holes in the translucent substrate based on the patterns thus formed in the step (a) (a penetrating process), the step (a) irradiating one of the surfaces of the translucent substrate with light so that the light passes through the translucent substrate toward the other surface, thereby exposing the photosensitive resin layers provided on the both surfaces of the translucent substrate.

The patterning process is a process for forming a pattern on a target object. More specifically, the patterning process exposes photosensitive resin layers provided on both surfaces of a substrate so that patterns of a plurality of through-holes are formed on the photosensitive resin layers. The target object is not especially limited, but may be a photosensitive resin layer formed on a surface of a substrate, for example. As a photosensitive resin composition for forming the photosensitive resin layer, cellulose resin, acrylic resin, resin having a urethane bond, or the like resin can be used, and a material containing the resin having a urethane bond is more preferable. For example, in a case where a through-hole is formed by a sandblasting method, with the use of a photosensitive resin containing the resin having a urethane bond, it is possible to improve sandblast resistance of the photosensitive resin. Further, the pattern formed on the photosensitive resin layer is not limited in any particular manner, but may be formed so as to correspond to through-holes. A method for forming the pattern may be, for example, a method in which a target object is exposed by being irradiated with light based on an intended pattern and the pattern thus transferred on the target object is developed. Exposing means for transferring the pattern is not especially limited provided that the pattern can be exposed. The exposing means may be, for example, a low-pressure mercury lamp, a high-pressure mercury lamp, an ultrahigh-pressure mercury lamp, a metal halide lamp, an argon gas laser, or the like.

In a developing method carried out after the exposure, an alkaline aqueous solution can be used as a developing solution. Examples of the alkaline aqueous solution encompass alkaline aqueous solutions of sodium hydrate, potassium hydrate, sodium carbonate, sodium silicate, sodium metasilicate, aqueous ammonia, ethylamine, n-propylamine, diethylamine, di-n-propylamine, triethylamine, methyl diethylamine, dimethylethanolamine, triethanolamine, tetramethylammonium hydroxide, tetraethylammonium hydroxide, pyrrole, piperidine, 1,8-diazabicyclo[5,4,0]-7-undecene, 1,5-diazabicyclo[4,3,0]-5-nonane, and the like. Further, it is also possible to use, as the developing solution, an aqueous solution prepared by adding, to such an alkaline aqueous solution, an appropriate amount of water-soluble organic solvent of ethanol or the like, or a surfactant.

A developing time is generally 1 to 30 minutes, and a developing method may be any of a liquid-building up method, a dipping method, a paddle method, and a spray developing method. After being developed, the photosensitive resin layers are washed with water for 30 to 90 seconds, and then the photosensitive resin layers may be post-baked. Patterns thus formed on the photosensitive resin layers may have, for example, a shape corresponding to through-holes to be formed afterward.

The penetrating process is a process of forming through-holes based on the patterns thus formed in the patterning process. A method for forming through-holes may be a sandblast method, an acid etching method, an alkaline etching method, a drilling process, or the like. Further, cone-shaped holes may be formed in both surfaces of a substrate so that each cone-shaped hole formed in one of the both surface is communicated with a corresponding cone-shaped hole formed in the other surface, inside the substrate. Alternatively, the substrate may be holed from one of the both surfaces thereof so as to form a through-hole. A shape of a through-hole to be formed is not limited to any particular shape, and may be, for example, an hourglass shape or a cylindrical shape. Further, a shape of an opening plane of the through-hole is not limited to any particular shape. In a case where the opening plane has, for example, a circular shape, its diameter may be in a range from 10 to 10,000 μm. Moreover, an aspect ratio (depth/width(diameter)) of the through-hole is not especially limited. It is preferable that the aspect ratio of the width and depth of the through-hole be, for example, in a range of 0.1 through 10.

The production method, according to the present invention, of a processed substrate may include an immersing process. The immersing process is a process of immersing, in acid, a substrate in which through-holes have been formed. By immersing, in acid, the substrate in which the through-holes have been formed, it is possible to remove burrs formed inside the through-holes during the penetrating process. In the description, the “burr” indicates a rough spot that is caused when a substrate or the like is holed, for example.

The acid to be used here is not especially limited to any particular type, and may be, for example, hydrofluoric acid. Further, an immersing time during which the substrate is immersed in acid depends on a concentration of the hydrofluoric acid to be used, but is preferably 1 to 60 minutes. By immersing the substrate during the immersing time in the above range, it is possible to favorably remove burrs caused in the through-holes.

The production method, according to the present invention, of a processed substrate may include a removing process. The removing process is a process to remove the photosensitive resin layers remaining on the substrate in which the through-holes have been thus formed. The removing process may be carried out before or after the immersing process, but is preferably carried out after the immersing process. For example, in a case where the removing process is carried out after the immersing process, it is possible to prevent erosion due to acid in surface regions of the substrate on which the photosensitive resin layers still remain. In this case, it is not necessary to polish the surfaces of the substrate after the immersing process. In other words, it is more preferable that the immersing process be carried out such that the substrate is immersed in acid with the photosensitive resin layers still remaining thereon. Further, the removing process is preferably such that the photosensitive resin layers are removed after the immersing process in which the substrate is immersed in acid with the photosensitive resin layers still remaining thereon.

Removing means is not especially limited provided that the removing means can remove the photosensitive resin layers from the substrate. For example, it is possible to remove the photosensitive resin layers in such a manner that the photosensitive resin layers are removed away from the substrate by use of a removing solution. In this case, the removing solution to be used may be, for example, an inorganic alkaline aqueous solution such as sodium hydrate or potassium hydrate, or an organic alkaline aqueous solution such as monoethanolamine or triethanolamine.

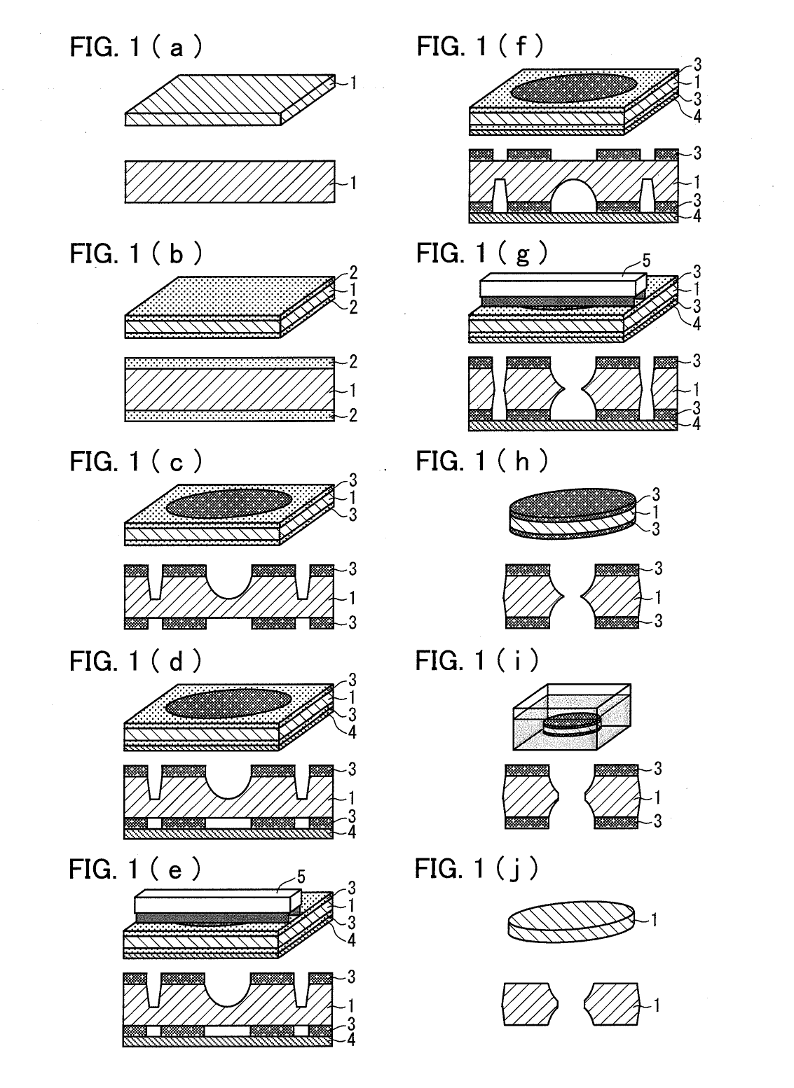

The following deals with one concrete example of how the production method according to the present embodiment proceeds, with reference to FIG. 1. However, the present invention is not limited to this example.

FIG. 1 schematically illustrates how a processed substrate is produced, in accordance with the present embodiment.

Initially, a substrate 1 made of the aforementioned material is prepared as a base material ((a) of FIG. 1), and photosensitive resin layers 2 are formed, with the use of a photosensitive resin composition, on surfaces of the substrate 1 ((b) of FIG. 1). In a case where the photosensitive resin composition for forming the photosensitive resin layers 2 is liquid, the photosensitive resin layers 2 can be formed by spin-coating, die-coating, or the like method. In a case where the photosensitive resin composition is a dry film, the photosensitive resin layers 2 can be formed by laminating or the like.

Then, one of the photosensitive resin layers 2 that is provided on one (a first surface) of the surfaces of the substrate 1 is irradiated with light via a mask so that the light passes through the substrate toward the other one of the photosensitive resin layers 2 that is provided on the other one (a second surface) of the surfaces of the substrate 1, thereby transferring patterns on the photosensitive resin layers 2 of the surfaces of the substrate 1. The patterns are transferred so that holes corresponding through-holes to be formed afterward are to be formed, and developed with the use of a developing solution or the like so as to form patterns 3 ((c) of FIG. 1, the patterning process). In the present embodiment, a photosensitive resin layer 2 thus patterned is just referred to as a “pattern 3”.

Further, a protection layer 4 constituted by an adhesive layer made of rubber or urethane is formed on that second surface side of the substrate 1 which is opposite to a first surface side to be holed, of the substrate 1 ((d) of FIG. 1). The first surface side to be holed is then holed by sandblast with the use of a sandblast polishing machine 5 so that holes reach in the vicinity of a center of the substrate 1 ((e) of FIG. 1). Further, in order that the second surface side opposite to the first surface side thus holed is holed in the same manner, a protection layer 4 is formed on the first surface side thus holed ((f) of FIG. 1), and then the second surface side is holed by sandblast so that holes reach in the vicinity of the center of the substrate 1 ((g) of FIG. 1, the penetrating process). In order to remove burrs caused during the penetrating process, a necessary portion of the substrate 1 in which the through-holes are formed as such is cut out ((h) of FIG. 1) and immersed in acid ((i) of FIG. 1, the immersing process). After that, the substrate 1 is taken out from the acid, and the patterns 3 made of residual photosensitive resin are removed, for example, with the use of a removing solution or the like (the removing process). Thus, a processed substrate is formed ((j) of FIG. 1).

In the present embodiment, the immersing process of immersing the substrate in acid is carried out after the substrate is subjected to the penetrating process. However, the immersing process may not be carried out. Further, the removing process of removing the photosensitive resin layers formed on the surfaces of the substrate may be carried out before or after an acid treatment (the immersing process). Besides, with the use of a large substrate, it is possible to obtain a plurality of processed substrates.

<3. Production Method According to Present Invention of Processed Glass Substrate>

A production method, according to the present invention, of a processed glass substrate may include the steps of: (a) forming photosensitive resin layers on both surfaces of a glass substrate; (b), after the step (a), forming at least one through-hole in the glass substrate; and (c), after the step (b), immersing the glass substrate in acid, with the photosensitive resin layers remaining on the both surfaces of the glass substrate (an immersing process).

In the description, a processed glass substrate indicates a glass substrate having a through-hole formed thereon. A processed glass substrate produced by the production method, according to the present invention, of a processed glass substrate can be used as a support substrate (support plate) for supporting a wafer when the wafer is subjected to polishing or the like process.

Various types of glass can be used as a material of the glass substrate. Examples of the material encompass: soda glass; alkali-free glass (for example, #1737, Eagle 2000, made by Corning International; NA32, NA35, made by NH Techno Glass Corporation); borosilicate glass (Tempax, Pyrex, and the like); and high-distortion-point glass (for example, PD-200 made by Asahi Glass Co., Ltd.). Further, a shape of the glass substrate is not limited to any particular shape. For example, the glass substrate may have a shape that can support a wafer, in a case where the glass substrate is used as a support substrate for supporting the wafer.

A photosensitive resin layer, a patterning method, a developing method carried out after exposure, a developing time, a method for forming through-holes in a glass substrate, and a shape of a through-hole are the same as those explained in the aforementioned <2. Production Method According to Present Invention of Processed Substrate>.

In the present embodiment, the immersing process is a process of immersing in acid a glass substrate in which a through-hole has been formed, with photosensitive resin layers still remaining on the glass substrate. In a case where the glass substrate in which the through-hole has been formed is immersed in acid as such, it is possible to remove burrs, which may be formed on an inner wall of the through-hole when the substrate is being holed. The “burr” indicates a rough spot caused, for example, when a glass substrate or the like is being holed. Further, since the glass substrate is immersed in acid with the photosensitive resin layers remaining on the glass substrate, the photosensitive resin layers protect the glass substrate, thereby making it possible to prevent erosion due to acid of surface portions of the glass substrate thus protected. For this reason, it is not necessary to carry out polishing or the like process to smooth the surfaces of the glass substrate, after the immersing process.

In the immersing process, the acid in which the glass substrate is immersed is not especially limited provided that burrs can be removed, and may be an immersion fluid containing hydrofluoric acid. In a case where hydrofluoric acid is used as the acid, a concentration of the hydrofluoric acid is not especially limited, but is preferably not less than 0.1% by mass but not more than 20% by mass, for example. When the concentration of the hydrofluoric acid is in the above range, it is possible to prevent a decrease in strength of the glass substrate. Moreover, an immersing time during which the glass substrate is immersed in acid depends on the concentration of the hydrofluoric acid to be used, but is preferably 1 to 60 minutes, and more preferably 3 to 30 minutes. By immersing the glass substrate in acid during the immersing time in the above range, it is possible to favorably remove burrs formed in inner walls of the through-hole.

Further, the production method, according to the present invention, of a processed glass substrate may further include the removing process the photosensitive resin layers, after the immersing process. A method for removing the photosensitive resin layers is not limited in any particular manner, and the photosensitive resin layers are removed by the aforementioned method.

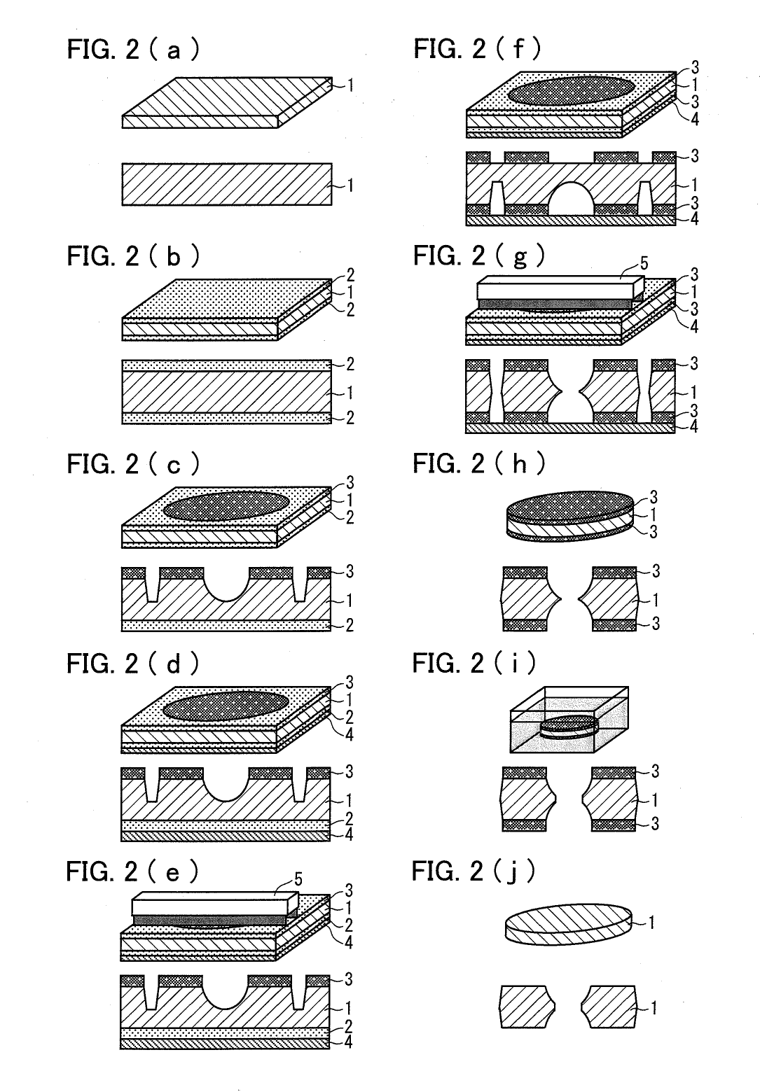

The following deals with one concrete example of how the production method according to the present embodiment proceeds, with reference to FIG. 2. However, the present invention is not limited to this example.

FIG. 2 schematically illustrates how a processed glass substrate is produced, in accordance with the present embodiment.

Initially, a glass substrate 1 is prepared as a base material ((a) of FIG. 2), and photosensitive resin layers 2 are formed, with the use of a photosensitive resin composition, on surfaces of the glass substrate 1 ((b) of FIG. 2). Photosensitive resin is not especially limited, but may be photosensitive resin containing the aforementioned resin having a urethane bond. The photosensitive resin layers 2 may be formed by spin-coating, die-coating, or the like method, in a case where the photosensitive resin composition for forming the photosensitive resin layers 2 is liquid. In a case where the photosensitive resin composition is a dry film, the photosensitive resin layers 2 can be formed by laminating or the like.

Then, one of the photosensitive resin layers 2 that is provided on one (a first surface) of the surfaces of the glass substrate 1 is irradiated with light via a mask, thereby transferring a pattern of holes corresponding to through-holes to be formed afterward, on the first surface of the glass substrate 1. As exposing means for exposing the pattern, the aforementioned exposing means can be used. The one of the photosensitive resin layers 2 is then developed based on the pattern thus transferred, with the use of a developing solution, so as to form a pattern 3 ((c) of FIG. 2, the patterning process). In the present embodiment, a photosensitive resin layer 2 on which a pattern is formed is just referred to as a “pattern 3”.

A protection layer 4 constituted by an adhesive layer made of rubber or urethane is then formed on the other surface side (second surface side) of the glass substrate 1 which is opposite to that first surface side of the glass substrate 1 on which the pattern 3 is formed ((d) of FIG. 2). Subsequently, the first surface side on which the pattern 3 is formed is etched, thereby forming holes so that the holes reach in the vicinity of a center of the glass substrate 1 ((e) of FIG. 2). An etching method is not limited in any particular manner provided that the glass substrate 1 is holed. In the present embodiment, a sandblast method employing a sandblast polishing machine 5 is adopted.

Then, with the use of the same method as above, the second surface side, of the glass substrate 1, which is opposite to the first surface side in which the holes are formed, is patterned so as to form a pattern 3 such that the pattern 3 is positioned right at positions of the holes thus formed in the first surface of the glass substrate 1 in the above process ((f) of FIG. 2). Furthermore, the second surface side is etched in accordance with the pattern 3 thus formed thereon, thereby forming holes so that the holes reach in the vicinity of the center of the glass substrate 1. At this time, each of the holes formed on the first surfaces side is communicated with a corresponding hole formed on the second surface sides, thereby forming a through-hole ((g) of FIG. 2, the penetrating process).

After that, a necessary portion in the glass substrate 1 in which the through-holes are formed as such is cut out ((h) of FIG. 2) and immersed in acid in order to remove burrs formed on inner walls of the through-holes during the penetrating process ((i) of FIG. 2, the immersing process). At this point, the photosensitive resin layers that have been used for forming the patterns 3 remain on surface portions, except for the through-holes, of the glass substrate 1. For this reason, only the inner walls of the through-holes are stress-relieved by the acid (that is, the burrs are removed).

After the glass substrate 1 is immersed in acid so that hole portions are stress-relieved as such, the photosensitive resin layers are stripped off and removed ((j) of FIG. 2, the removing process). A method for removing the photosensitive resin layers is not limited in any particular manner. For example, the photosensitive resin layers may be removed with the use of a removing solution or the like. In this way, a processed glass substrate having through-holes is formed. Further, with the use of a large glass substrate, it is possible to obtain a plurality of processed glass substrates.

The following deals with examples to further describe the embodiments according to the present invention in detail. It goes without saying that the present invention is not limited to the following examples and may be applied in many variations in terms of its details. The present invention is not limited to the description of the embodiments above, but may be altered by a skilled person within the scope of the claims. An embodiment based on a proper combination of technical means disclosed in different embodiments is encompassed in the technical scope of the present invention. Further, all literatures described in the description of the present invention are cited as references.

### Example 1

In the present example, a processed substrate was produced in the following manner.

Initially, photosensitive resin compositions (DFR (dry film resist) BF410, made by Tokyo Ohka Kogyo Co., Ltd.) that had been preheated at 80° C. for 5 minutes in advance were laminated on both surfaces of a 6-inch glass substrate (1737 glass, t=0.7 mm), which was a base material, so as to form photosensitive resin layers on the both surfaces of the glass substrate. At this time, a laminator was set to such conditions that a roll temperature was 100° C., a pressure was 0.25 MPa, and a speed was 1.0 m/min. Then, with the user of an ultrahigh-pressure mercury lamp (made by Hakuto Co., Ltd.; parallel light, exposure: 300 mJ/cm²), the glass substrate was irradiated with light from one of the both surfaces toward the other surface so that the photosensitive resin layers on the both surfaces were exposed and patterned. After that, patterns on the photosensitive resin layers were developed for 70 seconds with the use of a developing solution (0.25% Na₂CO₃ aqueous solution) at 30° C. in a spray-type developing machine. As such, 6-inch masks (φ: 150.5 mm, φ of an opening plane: 0.3 mm, pitch: 0.5 mm) were formed on the both surfaces of the glass substrate.

Subsequently, the glass substrate was subjected to sandblasting for about 120 minutes, with the use of SiC (silicon carbide) #600 (average particle diameter: 30 μm) under such conditions that a blast pressure was 0.16 MPa and a processing speed was 50 mm/min. This formed through-holes in the glass substrate. At this time, the number of the through-holes was about 120 per square centimeter. Thereafter, the photosensitive resin layers were removed from the glass substrate with the use of a removing solution (Product name “BF Stripper B”, made by Tokyo Ohka Kogyo Co., Ltd.) at 30° C. In this way, a processed substrate having through-holes was produced.

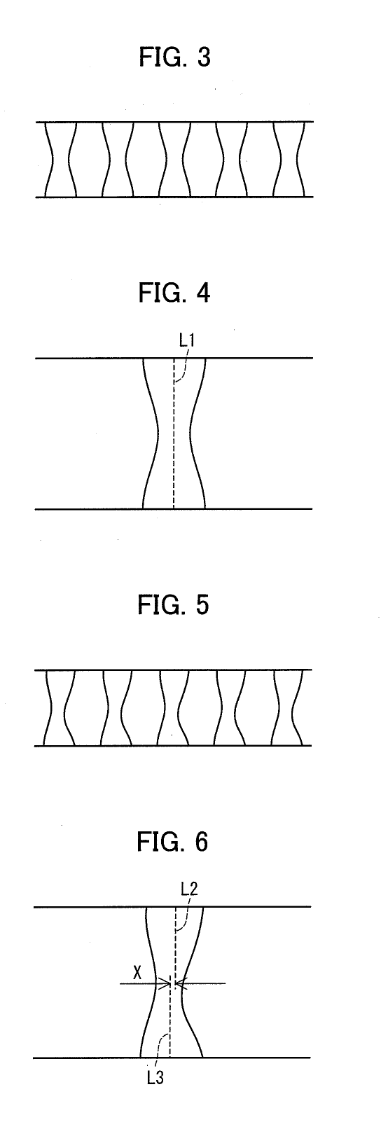

As a result of observing the processed substrate thus produced, it was demonstrated that a plurality of through-holes in each of which central axes of its opening planes were aligned, as shown in FIG. 3. Further, one of the through-holes was focused and observed. As a result of the observation, it was demonstrated that the through-hole had a depth of 0.7 mm, as shown in FIG. 4. More specifically, it was demonstrated that: (i) a central axis L1 in each of the through-hole was constituted by (a) a straight line which passes through a central point of one opening plane of the each of the through-holes and which is perpendicular to the opening plane and (b) a straight line which passes through a central point of the other opening plane of the each of the through-holes and which is perpendicular to the other opening plane; and (ii) there was no gap between the straight lines.

### Comparative Example 1

In Comparative Example 1, a processed substrate was produced under almost the same conditions as in the Example 1 except that, after photosensitive resin layers were formed on a glass substrate in the same manner as those in Example 1, each surface of the glass substrate was individually exposed and subjected to sandblasting. After one surface of the glass substrate was exposed, an alignment of holes was carried out before the other surface of the glass substrate was exposed. As a result of observing the processed substrate thus produced, it was demonstrated, as shown in FIG. 5, that a plurality of through-holes in each of which central axes of its opening planes were not aligned were formed.

Further, one of the through-holes was focused and observed. As a result of the observation, it was demonstrated, as shown in FIG. 6, that, in each of the through-holes, there was a gap (X) of about 6 to 20 μm between (a) a straight line (L2) which passes through a central point of one opening plane in the each of the through-holes and which is perpendicular to the opening plane and (b) a straight line (L3) which passes through a central point of the other opening plane in the each of the through-holes and which is perpendicular to the other opening plane.

### Example 2

In Example 2, a processed substrate was produced in almost the same manner as the production method of Example 1 except that a glass substrate was immersed in hydrofluoric acid before photosensitive resin layers were removed. Other than this point, the processed substrate of Example 2 was produced in the same manner as in Example 1.

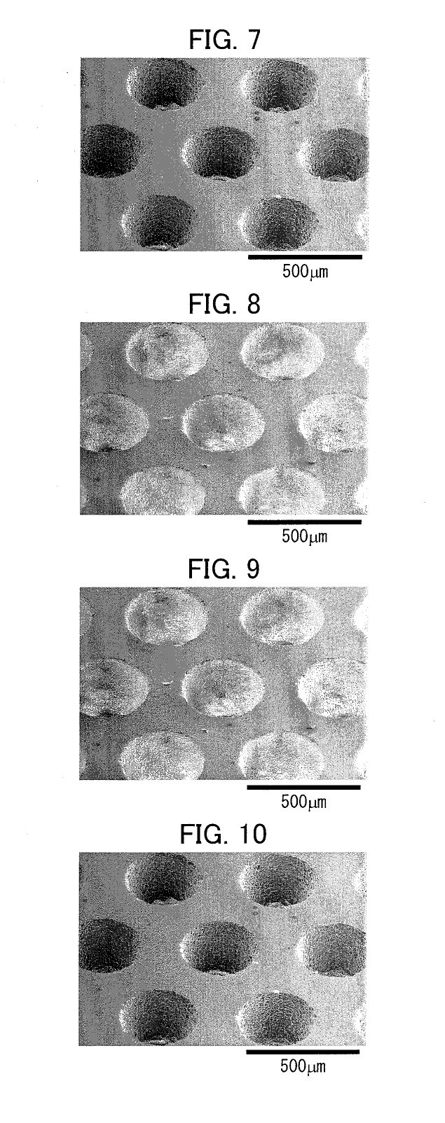

FIG. 7 illustrates a state of hole portions in the processed substrate thus produced. As illustrated in FIG. 7, it was demonstrated that the hole portions of the glass substrate immersed in hydrofluoric acid was stress-relieved because burrs were removed, in comparison with hole portions in the glass substrate of Example 1, as illustrated in FIG. 8, which was not subjected to hydrofluoric acid treatment.

### Example 3

In the present example, a processed glass substrate was produced in the following manner.

Initially, photosensitive resin compositions (DFR (dry film resist) BF410, made by Tokyo Ohka Kogyo Co., Ltd.) that had been preheated at 80° C. for 5 minutes in advance were laminated on both surfaces of a 6-inch glass substrate (1737 glass, t=0.7 mm), which was a base material, so as to form photosensitive resin layers on the both surfaces of the glass substrate. At this time, a laminator was set to such conditions that a roll temperature was 100° C., a pressure was 0.25 MPa, and a speed was 1.0 m/min. Then, with the user of an ultrahigh-pressure mercury lamp (made by Hakuto Co., Ltd.; parallel light, exposure: 300 mJ/cm²), one (first surface) of the surfaces of the glass substrate was irradiated with light via a mask so as to form a pattern. Then, the pattern on the first surface was developed for 70 seconds with the use of a developing solution (0.25% Na₂CO₃ aqueous solution) at 30° C. in a spray-type developing machine. As such, a 6-inch mask (φ: 150.5 mm, φ of an opening plane: 0.3 mm, pitch: 0.5 mm) was formed on the first surface of the glass substrate.

Subsequently, the glass substrate was subjected to sandblasting for about 120 minutes, with the use of SiC (silicon carbide) #600 (average particle diameter: 30 μm) under such conditions that a blast pressure was 1.5 kg/cm², a processing speed was 50 mm/min, and the number of passes was 15. In this process, holes were formed in the first surface of the glass substrate such that the holes reached in the vicinity of a center of the glass substrate in a thickness direction of the glass substrate.

Further, the other surface (second surface), of the glass substrate, which was opposite to the first surface that had been subjected to the above processes, was also patterned and subjected to sandblasting, in the same manner as above. Thus, through-holes were formed in the glass substrate.

After that, the glass substrate was immersed in hydrofluoric acid (at a room temperature, a concentration of the hydrofluoric acid: 3%) for 10 minutes. The glass substrate was then taken out from the hydrofluoric acid. Subsequently, the photosensitive resin layers were removed with the use of a removing solution (Product name “BF Stripper B”, made by Tokyo Ohka Kogyo Co., Ltd.) at 30° C. In this way, a processed glass substrate having through-holes was produced.

The processed glass substrate thus produced was observed. FIG. 9 illustrates a glass substrate that was not subjected to an acid treatment, and FIG. 10 illustrates a glass substrate that was subjected to the acid treatment. After the glass substrate was subjected to the acid treatment, hole portions were formed as illustrated in FIG. 10. In comparison with those of the glass substrate as illustrated in FIG. 9, which was not subjected to the acid treatment, it was clearly demonstrated that inner walls of the hole portions of the glass substrate of FIG. 10 were stress-relieved.

### Example 4

A processed glass substrate of the present example was produced in accordance with the production method of Example 3 except that the concentration of the hydrofluoric acid and the immersing time in the acid treatment were changed.

More specifically, the concentration of hydrofluoric acid was changed to 0.2%, 1.0%, 3.0%, or 10.0%. The immersing time was changed to 1 min, 3 min, 10 min, or 30 min. With the above arrangements, qualitative evaluations were conducted on how much hole portions were stress-relieved. Specifically, the glass substrates were evaluated as follows: “I” indicates a condition that caused insufficient stress relief, “G” indicates a condition that caused good stress relief, and “E” indicates a condition that caused excellent stress relief. Evaluation results are shown in Table 1.

TABLE 1

| | |
|---|---|
| | Concentration of |
| Time | Hydrofluoric acid [%] |

| [min] | 0.2 | 1.0 | 3.0 | 10.0 |
|---|---|---|---|---|
| 1 | I | I | I | I |
| 3 | I | I | I | E |
| 10 | I | I | E | E |
| 30 | G | E | E | E |

As shown in Table 1, under either condition, at least small stress relief was observed. Under conditions evaluated as “G”, stress relief better than that under conditions evaluated as “I” was observed. Further, under conditions evaluated as “E”, extremely excellent stress relief was observed.

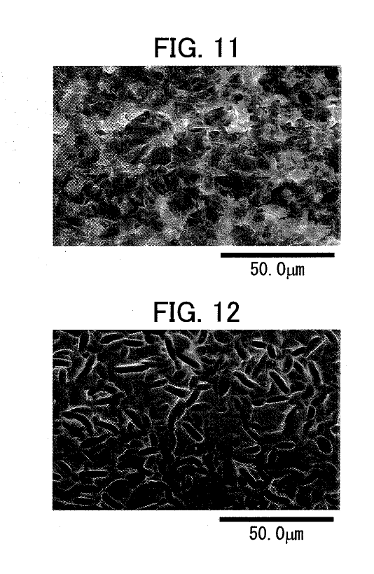

Further, FIG. 11 illustrates a result of observing, with the use of an electronic microscope, stress relief caused under a condition that the concentration of the hydrofluoric acid was 0.2% and the immersing time was 1 min, among the conditions evaluated as “I” in Table 1. Further, FIG. 12 illustrates a result of observing, with the use of an electronic microscope, stress relief caused under a condition that the concentration of the hydrofluoric acid was 10.0% and the immersing time was 30 min, among the conditions evaluated as “E” in Table 1. As comparing FIG. 11 with FIG. 12, it was found that a condition with a higher concentration of the hydrofluoric acid and a longer immersing time caused inner walls of holes to be smoother. Even under the conditions evaluated as “E”, photosensitive resin layers were never stripped off due to immersion in acid. Further, under all the conditions, it was demonstrated that surfaces of the glass substrates were kept smooth due to DFRs.

The above results were obtained with the use of a 1737 glass as the glass substrate. In a case where a substrate made of other glass compositions is used, the aforementioned conditions may be different.

The processed substrate and the production method thereof, according to the present invention, allows (i) easy production of a processed substrate with high productivity and (ii) the processed substrate thus produced to have through-holes whose central axes are aligned. For this reason, they can be applied to a production of a semiconductor chip for use in a small tool such as a mobile communication appliance.

The embodiments and concrete examples of implementation discussed in the foregoing detailed explanation serve solely to illustrate the technical details of the present invention, which should not be narrowly interpreted within the limits of such embodiments and concrete examples, but rather may be applied in many variations within the spirit of the present invention, provided such variations do not exceed the scope of the patent claims set forth below.

1. A processed substrate comprising a translucent substrate having a plurality of through-holes, each of the plurality of through-holes being such that there is a gap in a range from 0 to 5 μm between (a) a straight line which passes through a central point of an opening plane of the each of the plurality of through-holes and which is perpendicular to the opening plane and (b) a straight line which passes through a central point of the other opening plane of the each of the plurality of through-holes and which is perpendicular to the other opening plane.

2. The processed substrate as set forth in claim 1, wherein the translucent substrate is made of glass.

3. A method for producing a processed substrate including a translucent substrate having a plurality of through-holes, said method comprising the steps of:
(a) forming, by exposure, patterns of a plurality of through-holes on photosensitive resin layers provided on both surfaces of a translucent substrate; and
(b) forming through-holes in the translucent substrate based on the patterns thus formed in the step (a),
the step (a) irradiating one of the both surfaces of the translucent substrate with light so that the light passes through the translucent substrate toward the other surface, thereby exposing the photosensitive resin layers provided on the both surfaces of the translucent substrate.

4. The method as set forth in claim 3, wherein:
the step (b) forms cone-shaped holes in each of the both surfaces of the translucent substrate so that each cone-shaped hole formed in one of the both surfaces is communicated with a corresponding cone-shaped hole formed in the other surface, inside the translucent substrate.

5. The method as set forth in claim 3, further comprising, after the step (b), the step of:
(c) immersing the translucent substrate in acid with the photosensitive resin layers remaining on the both surfaces of the translucent substrate.

6. The method as set forth in claim 5, further comprising, after the step (c), the step of:
(d) removing the photosensitive resin layers.

7. A method for producing a processed glass substrate, comprising the steps of:
(a) forming photosensitive resin layers on both surfaces of a glass substrate;
(b) after the step (a), forming at least one through-hole in the glass substrate; and
(c) after the step (b), immersing the glass substrate in acid with the photosensitive resin layers remaining on the both surfaces of the glass substrate.

8. The method as set forth in claim 7, further comprising, after the step (c), the step of:
(d) removing the photosensitive resin layers.

9. The method as set forth in claim 7, wherein:
the acid is an immersing solution containing hydrofluoric acid.

10. The method as set forth in claim 9, wherein:
a concentration of the hydrofluoric acid is not less than 0.1% by mass but not more than 20% by mass.

11. The method as set forth in claim 7, wherein:
a diameter of the at least one through-hole is not less than 10 μm but not more than 10,000 μm.

12. The method as set forth in claim 7, wherein:
the at least one through-hole includes a plurality of through-holes, and
a distance between centers of through-holes positioned closest to one another among the plurality of through-holes is not less than 10 μm but not more than 10,000 μm.

13. The method as set forth in claim 7, wherein:
a photosensitive resin composition for forming the photosensitive resin layers contains resin having a urethane bond.
